(19) United States
(12) Patent Application Publication
(10) Pub. No.: US 2026/0082909 A1
(43) Pub. Date: Mar. 19, 2026

(54) SEMICONDUCTOR PACKAGE ASSEMBLY WITH DUAL HEAT SINK PLATES

(71) Applicant: STATS ChipPAC Pte. Ltd., Singapore (SG)

(72) Inventors: JiSeon LEE, Incheon (KR); EunHee MYUNG, Gyeonggi-do (KR)

(21) Appl. No.: 19/286,278

(22) Filed: Jul. 31, 2025

(30) Foreign Application Priority Data
Sep. 14, 2024 (CN) 202411293279.7

(51) Int. Cl. H01L 23/367; H01L 21/48; H01L 21/56; H01L 23/00; H01L 25/10

(52) U.S. Cl. CPC H10W 40/228; H10W 40/22; H10W 70/023; H10W 70/093; H10W 90/00; H10W 74/016; H10W 74/15; H10W 90/724; H10W 90/734

(57) ABSTRACT

A semiconductor package assembly comprises a first semiconductor package with a first semiconductor element and a first set of conductive patterns exposed thereon; an interposer mounted thereon via a set of interconnect structures, wherein the interposer has a second set of conductive patterns on its back surface aligned with the first set, electrically connected through the interconnects; and the interposer includes at least one opening extending through it; a second semiconductor package mounted on the front surface of the interposer; and a heat sink, comprising a back heat sink plate mounted thereon between the first package and the interposer, thermally coupled with the first semiconductor element; a front heat sink plate mounted thereon between the interposer and the second package, in contact with the interposer's front surface; and a heat sink plate connector extending through the opening, connecting the plates for heat transfer.

### TECHNICAL FIELD

The present application generally relates to semiconductor technologies, and more particularly, to a semiconductor package assembly with an interlayer cooling pathway, and a method for making a semiconductor package assembly.

### BACKGROUND OF THE INVENTION

The semiconductor industry is constantly faced with complex integration challenges as consumers want their electronics to be smaller, faster and higher performance with more and more functionalities packed into a single device. In some semiconductor packages, a Package-in-Package (PiP) or Package-on-Package (PoP) process is applied, which combines two or more integrated circuit (IC) packages together. The PiP or PoP devices can more efficiently use space, and reduce lengths of signal paths between the packages. In a typical PiP or PoP device, one or more pre-molded semiconductor packages may be mounted onto another semiconductor package through an interposer or other similar structures.

However, it is noted that certain semiconductor elements such as logic circuit chips or high bandwidth memory chips in the PiP or PoP devices may generate significant heat during operation which may not be well dissipated to the external environment due to the compact package structure of the PiP or PoP devices. Therefore, a need exists for further improvement to semiconductor package assemblies with integrated semiconductor elements.

### SUMMARY OF THE INVENTION

An objective of the present application is to provide a semiconductor package assembly with dual heat sink plates.

According to an aspect of the present application, a semiconductor package assembly is disclosed. The semiconductor package assembly comprises: a first semiconductor package comprising a first semiconductor element and a first set of conductive patterns both exposed from a front surface of the first semiconductor package; an interposer mounted on the front surface of the first semiconductor package via a set of interconnect structures, wherein the interposer comprises at its back surface a second set of conductive patterns which are aligned with the first set of conductive patterns such that the first and second sets of conductive patterns are electrically connected with each other through the set of interconnect structures; and wherein the interposer further comprises at least one opening extending through the interposer; a second semiconductor package mounted on a front surface of the interposer; and a heat sink; wherein the heat sink comprises: a back heat sink plate mounted between the first semiconductor package and the interposer, and thermally coupled with the first semiconductor element; a front heat sink plate mounted between the interposer and the second semiconductor package, and being in contact with the front surface of the interposer; and a heat sink plate connector extending through the at least one opening and connecting the back heat sink plate and the front heat sink plate to allow heat to be transferred from the back heat sink plate to the front heat sink plate.

According to another aspect of the present application, a method for making a semiconductor package assembly is provided. The method comprises: providing a first semiconductor package, wherein the first semiconductor package comprises a first semiconductor element and a first set of conductive patterns exposed from a front surface of the first semiconductor package; attaching a set of interconnect structures on the front surface of the first semiconductor package and electrically connecting the set of interconnect structures with the first set of conductive patterns; mounting a back heat sink plate on the front surface of the first semiconductor package to at least thermally couple the back heat sink plate with the exposed first semiconductor element, wherein a heat sink plate connector extends away from the back heat sink plate; mounting an interposer on the front surface of the back heat sink plate, wherein the interposer comprises at its back surface a second set of conductive patterns which are aligned with the first set of conductive patterns such that the first and second sets of conductive patterns are electrically connected with each other through the set of interconnect structures, and wherein the interposer comprises at least one opening extending through the interposer to allow the heat sink plate connector to pass through the at least one opening; mounting a second semiconductor package on a front surface of the interposer; and mounting a front heat sink plate on the front surface of the interposer to connect the front heat sink plate with the back heat sink plate through the heat sink plate connector.

According to a further aspect of the present application, a method for making a semiconductor package assembly is provided. The method comprises: providing a first semiconductor package, wherein the first semiconductor package comprises a first semiconductor element and a first set of conductive patterns exposed from a front surface of the first semiconductor package; attaching a set of interconnect structures on the front surface of the first semiconductor package and electrically connecting the set of interconnect structures with the first set of conductive patterns; providing an interposer assembly; wherein the interposer assembly comprises an interposer with a second set of conductive patterns at a back surface of the interposer, and at least one opening passing through the interposer; the interposer assembly further comprises a back heat sink plate attached on the back surface of the interposer and a front heat sink plate attached on the front surface of the interposer; and wherein the back heat sink plate and the front heat sink plate are thermally connected with each other through a heat sink plate connector that passes through the at least one opening; mounting the interposer assembly on the front surface of the first semiconductor package via the set of interconnect structures, wherein the second set of conductive patterns are aligned with the first set of conductive patterns such that the first and second sets of conductive patterns are electrically connected with each other through the set of interconnect structures; and mounting the second semiconductor package on the front surface of the interposer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a semiconductor package assembly according to an embodiment of the present application.

FIG. 1B illustrates an exemplary layout of a back heat sink plate on a first semiconductor package of the semiconductor package assembly shown in FIG. 1A.

FIG. 1C illustrates an exemplary layout of a front heat sink plate on a first semiconductor package of the semiconductor package assembly shown in FIG. 1A.

FIG. 2 illustrates a semiconductor package assembly according to an embodiment of the present application.

FIG. 3 illustrate a semiconductor package assembly according to an embodiment of the present application.

FIGS. 4A to 4H illustrate a method for making a semiconductor package assembly according to an embodiment of the present application.

FIGS. 5A to 5E illustrate another method for making a semiconductor package assembly according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, conventional semiconductor package assemblies may not have a satisfactory heat dissipation performance due to their compact structure as well as significant heat generated by semiconductor elements encapsulated within the semiconductor package assemblies. To address the heat dissipation issue, the inventors of the present application have conceived an invention of integrating a heat sink into a semiconductor package assembly to dissipate heat generated inside the semiconductor package assembly out. The heat sink may have connected heat sink plates that are mounted onto both sides of an internal interposer of the semiconductor package assembly so as to be in direct contact with the internal semiconductor elements. In this way, the heat dissipation performance of the semiconductor package assembly can be improved significantly.

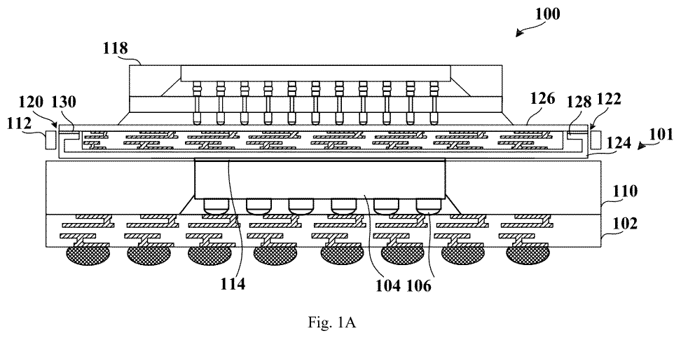

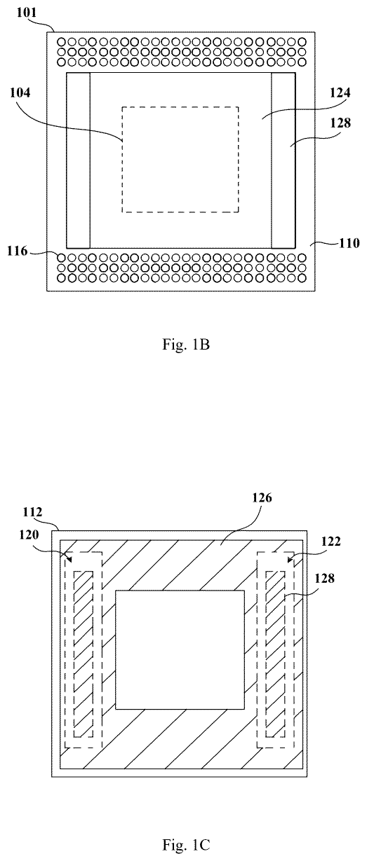

FIG. 1A illustrates a semiconductor package assembly 100 according to an embodiment of the present application. As shown in FIG. 1A, the semiconductor package assembly 100 incorporates two semiconductor packages that are stacked together through an interposer. Therefore, a semiconductor element encapsulated within a lower one of the two semiconductor packages may be embedded within the entire semiconductor package assembly 100 and relatively far away from the external environment. It should be noted that although two semiconductor packages are illustrated in FIG. 1A as an example, more semiconductor packages may be integrated within the semiconductor package assembly 100, as desired.

As shown in FIG. 1A, the semiconductor package assembly 100 includes a first semiconductor package 101. The first semiconductor package 101 may include a first substrate 102, and at least one semiconductor element 104 mounted on the first substrate 102. In some embodiments, the semiconductor element 104 may be a semiconductor die or a smaller semiconductor package which may be mounted on a front surface of the first substrate 102 via solder bumps 106 or similar structures. Furthermore, a set of conductive structures (not shown) such as stacked solder bumps or copper posts may be mounted on the front surface of the first substrate 102 in parallel with the first semiconductor element 104. A mold cap 110 is formed on the first substrate 102 to encapsulate the first semiconductor element 104 and the set of conductive structures, and protect them from the external environment and damages. In some embodiments, the mold cap 110 may be made, partially or in all, of a polymer composite material such as epoxy resin with filler, epoxy acrylate with filler, or polymer with proper filler.

The first semiconductor package 101 has a front surface (facing upward in the direction shown in FIG. 1A) and a back surface that is opposite to the front surface. Below the back surface, solder bumps may be mounted to the first semiconductor package 101 to allow the entire semiconductor package assembly 100 to be mounted or connected to an external device when needed. On the other hand, the front surface of the first semiconductor package serves as a platform and support surface for other components of the semiconductor package assembly 100. The mold cap 110 is so formed that its front surface is a part of the front surface of the first semiconductor package 101, while the first semiconductor element 104 and the set of conductive structures are exposed from the front surface of the first semiconductor package 101, as the other part of the front surface of the first semiconductor package 101. In some embodiments, the mold cap 110 may be formed with an excess amount of a molding material over the first semiconductor element 104 and the set of conductive structures, which may later be attenuated to some extent to expose the front surfaces of the first semiconductor element 104 and the set of conductive structures. With the set of conductive structures exposed as a set of conductive patterns, the other components formed above the first semiconductor package 101 can be electrically coupled to the first substrate 102 and the solder bumps thereunder; with the first semiconductor element 104 exposed and not covered by the mold cap 110, a heat dissipation path is formed through the exposed front surface of the first semiconductor element 104 to allow directly dissipating heat generated by the first semiconductor element 104.

Still referring to FIGS. 1A and 1B, an interposer 112 is mounted on the front surface of the first semiconductor package 101 via a set of interconnect structures 116. In particular, the interposer 112 includes at its back surface another set of conductive patterns such as contact pads, which are aligned with the set of conductive patterns on the front surface of the first semiconductor package 101. In this way, the two sets of conductive patterns can be electrically connected with each other through the set of interconnect structures 116. In some embodiments, the interposer 112 may include one or more insulating or passivation layers, one or more conductive vias formed through the insulating layers, and one or more conductive layers formed over or between the insulating layers. The conductive vias and conductive layers form together various interconnect structures in the interposer 112. Since the interposer 112 is supported on the first semiconductor package 101 by the interconnect structures 116 and thus is not in direct contact with the first semiconductor package 101, a gap between the interposer 112 and the first semiconductor package 101 is formed. A height of the gap is generally equal to a height of the set of interconnect structures 116. In some embodiments, the set of interconnect structures 116 may be solder bumps, while in some alternative embodiments, the set of interconnect structures 116 may be other interconnect components such as metal posts or e-bar modules. Besides electrically connecting the two sets of conductive patterns with each other, the interconnect structures 116 may provide mechanical support for the interposer 112 as well as components mounted thereon.

In the embodiment shown in FIG. 1A, a back heat sink plate 124 is mounted between the first semiconductor package 101 and the interposer 112. The back heat sink plate 124 can be in thermal contact with the exposed first semiconductor element 104, either directly or indirectly through a thermal interface material layer 114. A first opening 120 and a second opening 122 are formed in the interposer 112 on opposite sides of the interposer 112 with respect to a second semiconductor package which is mounted above the interposer 112. The back heat sink plate 124 can transfer heat from the first semiconductor element 104 for heat dissipation, as a part of a heat sink. Furthermore, the heat sink further includes a heat sink plate connector 128 that includes respective portions extending through the first opening 120 and the second opening 122. In the embodiment, the interposer 112 has two openings 120 and 122, and in some other embodiments, the interposer 112 may have one opening or three or more openings that extend through the interposer 112 vertically. Accordingly, the heat sink plate connector 128 can extend through the at least one opening of the interposer 112, to connect the back heat sink plate 124 under the interposer 112 with a front heat sink plate 126 which is mounted above the interposer 112. In this way, the front and back heat sink plates 126 and 124 can be mechanically and thermally connected with each other, to allow heat generated by the first semiconductor element 104 to be transferred from the back heat sink plate 124 to the front heat sink plate 126. The front heat sink plate 126 may be exposed to the environment or further connected to other heat dissipation components, to provide a heat dissipation heat from the interior to the exterior of the semiconductor package assembly 100. In some embodiments, the heat sink plate connector 128 can be integrally formed with the back heat sink plate 124 and extends from the back heat sink plate 124 to the front heat sink plate 126, and has an increased contact surface at a position where it is connected to the front heat sink plate 126 to allow for connection with the front heat sink plate 126 through the thermal interface material layer 130. In some embodiments, the heat sink plate connector 128 can be discrete parts that are attached to the back heat sink plate 124 and further to the front heat sink plate 126 using adhesive or similar materials. For example, the heat sink plate connector 128 may be shaped as blocks, rods, L-shaped bars, or C-shaped bars. It can be appreciated that the heat sink plate connector 128 should have sufficient strength to maintain the connection between the back heat sink plate 124 and the front heat sink plate 126. In some embodiments, the heat sink plate connector 128 may be formed of the same material as the front and back heat sink plates, for example, copper, aluminum or silver or other suitable thermally conductive materials.

It can be appreciated that, other than being in contact with the exposed first semiconductor component 104, the back heat sink plate 124 may be in contact with the interposer 112 directly (while avoiding direct contact between the conductive patterns on the back surface of the interposer layer 112 and the back sink plate 124). In other wors, the back sink plate 124 generally occupies a gap between the interposer 112 and the first semiconductor package 101, and has a thickness equal to a height of the gap. As such, the back heat sink plate 124 can provide internal mechanical support for the semiconductor package assembly 100 to improve its mechanical strength. In some embodiments, the back heat sink plate 124 may not occupy the entire height of the gap, which may be occupied by an insulating layer formed additionally, for example an underfill layer. The underfill layer may also occupy the remaining regions of the gap which is not filled by the back heat sink plate 124.

In some embodiments, the second semiconductor package 118 may be mounted on the interposer 112, for example, via a set of solder bumps or similar conductive structures. In some embodiments, the front heat sink plate 126 may be attached after the mounting of the second semiconductor package 118, and thus, the front heat sink plate 126 may be shaped as a frame and has a central window for passing the second semiconductor package 118, which is connected with the front surface of the interposer 112 in advance. The frame-shaped front heat sink plate 126 can have a peripheral region around its central window, which provides sufficient area for connecting with the heat sink plate connector 128 and for heat dissipation to the external environment. It can be appreciated that, in some alternative embodiments, the front heat sink plate 126 may have some shapes, as long as it is not conflicting with the second semiconductor package 118.

Furthermore, besides the exposed front surface of the first semiconductor element 104, the back heat sink plate 124 may extend along certain other regions of the front surface of the first semiconductor package 101, to absorb heat generated or accumulated in these regions. For example, the back heat sink plate 124 may be adjacent to or in proximity to the solder bumps 116, and thus can draw heat from the solder bumps 116.

In some embodiments, the back heat sink plate 124 is formed of a metal material or an alloy, which has a good thermal conductivity and is suitable for heat dissipation. It can be appreciated that the back heat sink plate 124 should be electrically isolated from the solder bumps 116, to avoid undesired electrical connection between the solder bumps 116 and other conductive structures. For example, a buffer layer of an insulating material may be filled between the solder bumps 116 and the back heat sink plate 124, and/or between the back heat sink plate 124 and other contact pads on a back surface of the interposer 112. In some other embodiments, the back heat sink plate 124 may be made of other materials with a good thermal conductivity.

As the first semiconductor element 104 may have a square or rectangular layout, the back heat sink plate 124 may preferably have a similar layout. It can be appreciated that the back heat sink plate 124 may take other suitable shapes to increase its contact area with the first semiconductor package 101, or especially with the first semiconductor element 104.

FIG. 1B illustrates an exemplary layout of the back heat sink plate 124 on the first semiconductor package 101 of the semiconductor package assembly 100 shown in FIG. 1A. As shown in FIG. 1B, the front surface of the first semiconductor element 104 is exposed and not covered by the mold cap 110 of the first semiconductor package 101. A central portion of the back heat sink plate 124 is substantially overlapping the exposed front surface of the first semiconductor element 104 to absorb heat therefrom. Furthermore, the solder bumps 116 which are mounted on the first semiconductor package 101 may be arranged around the first semiconductor element 104, and thus may not be in direct contact with the back heat sink plate 124.

FIG. 1C illustrates an exemplary layout of the front heat sink plate 126 shown in FIG. 1A. As shown in FIG. 1C, the front may be shaped as a frame and be mounted on the front surface of the interposer 112. The front heat sink plate 126 also has a peripheral region around its central window, which provides sufficient area for connecting with the heat sink plate connector 128 and for heat dissipation to the external environment. The front heat sink plate 126 and the heat sink plate connector 128 are filled with shadows to distinguish from the first opening 120 and the second opening 122.

Referring back to FIG. 1A, as aforementioned, the second semiconductor package 118 is further mounted on a front surface of the interposer 112, to increase the integration level of the entire semiconductor package assembly 100. The second semiconductor package 118 may have a second substrate and a second semiconductor element mounted on the second substrate, similar as the configuration and structure of the first semiconductor package 101. Moreover, the front heat sink plate 126 with the central window can be connected to the heat sink plate connector 128 through the thermal interface material layer 130 without hindering the mounting of the second semiconductor package 118, and thus allowing heat to be transferred from the first semiconductor package 101 to the front heat sink plate 126.

In the embodiment shown in FIG. 1A, the second semiconductor package 118 includes a second semiconductor element such as a semiconductor die or smaller semiconductor package mounted on a second substrate, and the second semiconductor element is away from the first semiconductor element 104 of the first semiconductor package 101. In some alternative embodiments, especially when three or more semiconductor packages are stacked together, the second semiconductor package may be mounted on the interposer in a similar way as the first semiconductor package, and the second semiconductor element may also be facing towards the interposer from the front surface of the interposer. That is, the two semiconductor packages may be mounted substantially symmetrically with respect to the interposer.

As shown in FIGS. 1A and 1B, the heat sink which is integrated within the semiconductor package assembly 100 not only provides a heat dissipation path to the external environment, but also improves the reliability of the assembly. In particular, in some cases where a big (e.g., bigger than 3 mm) semiconductor die or chip mounted may easily warp due to the accumulation of internal stress, while the heat sink plates 124 and 126 mounted on the interposer 112 can serve as a stiffener for the second semiconductor package 118 and the first semiconductor element 104 to compensate the undesired stress and provide mechanical support, while dissipating heat from the first semiconductor element 104 to the environment.

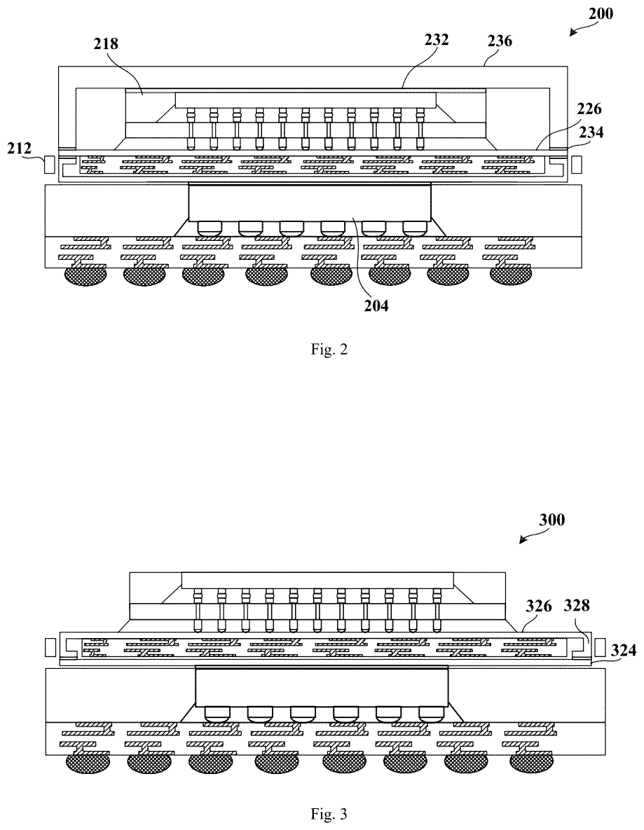

FIG. 2 illustrates a semiconductor package assembly 200 according to an embodiment of the present application. Different from the semiconductor package assembly 100 shown in FIG. 1A, more heat sink(s) can be integrated within the semiconductor package assembly 200.

As shown in FIG. 2, an additional heat sink 236 is mounted on an interposer 212 of the semiconductor package assembly 200. The additional heat sink 236 can be shaped as a cover and defines a cavity for accommodating a second semiconductor package 218 which is also mounted on the interposer 212. In some embodiments, the second semiconductor package 218 may be thermally connected with the additional heat sink 236 through a thermal interface material layer 232 to allow heat to be transferred from the second semiconductor package 218 to the additional heat sink 236. Furthermore, the additional heat sink 236 can be connected to a front heat sink plate 226 through a thermal interface material layer 234 to allow heat to be transferred from a first semiconductor package 204 below the interposer 212 to the additional heat sink 236, and thus provide an additional heat dissipation path from the interior to the exterior of the semiconductor package assembly 200. It can be appreciated that, in some alternative embodiments, the additional heat sink 236 may have some other shapes, as long as it can be connected with both the front heat sink plate 226 and the second semiconductor package 218.

FIG. 3 illustrates a semiconductor package assembly 300 according to an embodiment of the present application. As shown in FIG. 3, the structure of the semiconductor package assembly 300 is similar to that of the semiconductor assembly 100 shown in FIG. 1A, differing only in a heat sink plate connector 328 that connects front and back heat sink plates 324 and 326 together. In particular, the heat sink plate connector 328 can be integrally formed with the front heat sink plate 326, instead of with the back heat sink plate 324, and extends from the front heat sink plate 326 to the back heat sink plate 324 and has an increased contact surface at a position where it is connected to the back heat sink plate 324 to allow for connection with the back heat sink plate 324 through the thermal interface material layer 330.

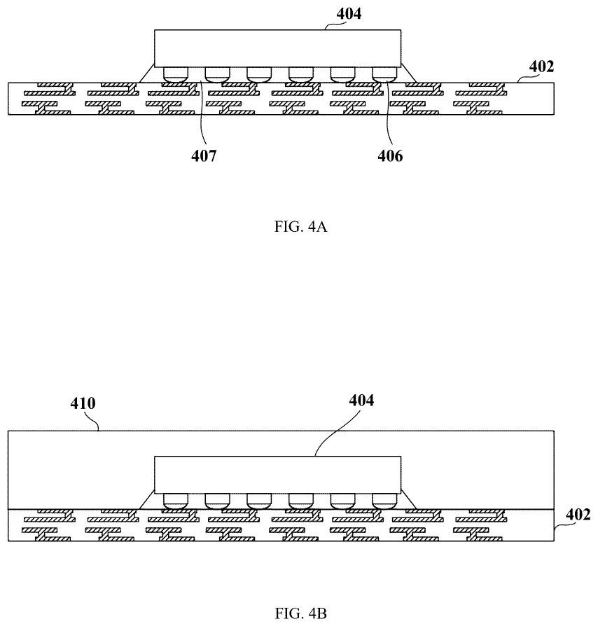

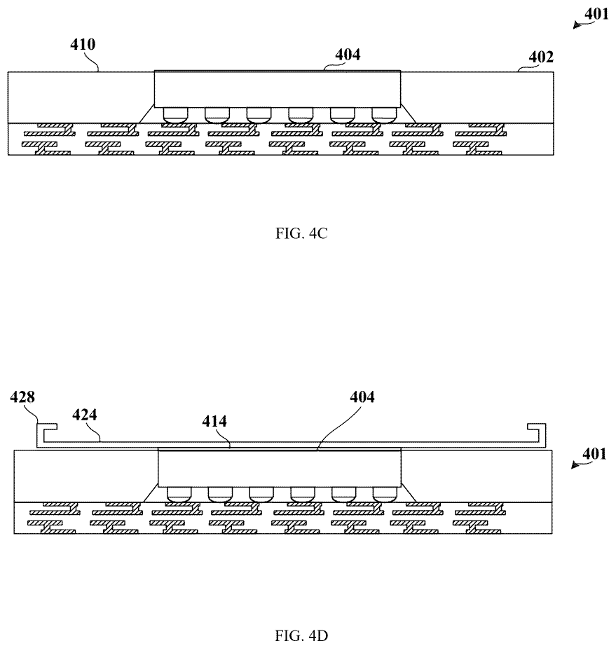

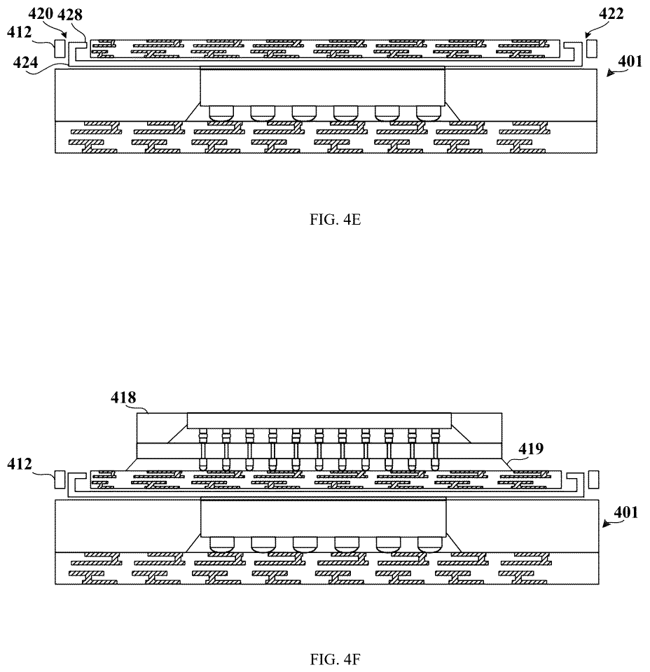

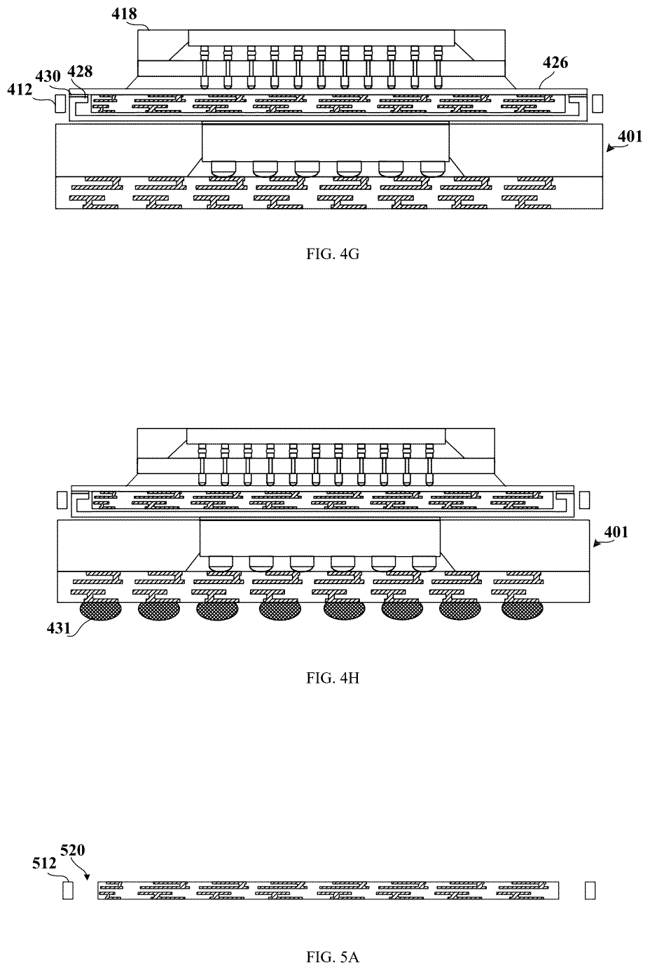

FIGS. 4A to 4H illustrate a method for making a semiconductor package assembly according to an embodiment of the present application. The method may be used to make the semiconductor package assembly 100 shown in FIG. 1A, the semiconductor package assembly 200 shown in FIG. 2, or the semiconductor package assembly 300 shown in FIG. 3 with some modifications.

As shown in FIG. 4A, a first substrate 402 is provided, a first semiconductor element 404 is mounted onto the first substrate 402 via solder bumps 406. In some embodiments, an underfill material 407 may be filled between the first semiconductor element 404 and the first substrate 402 and around the solder bumps 406, to enhance the attachment of the first semiconductor element 404 to the first substrate 402. Next, a mold cap 410 may be formed on the first substrate 402 to encapsulate the first semiconductor element 404, as shown in FIG. 4B. For example, the mold cap 410 may be formed using an injection molding process or a compression molding process. In some other embodiments, the mold cap 410 may be formed using paste printing, transfer molding, liquid encapsulant molding, vacuum lamination, spin coating, or any other suitable process.

Next, as shown in FIG. 4C, an excess portion of the molding material of the mold cap 410 that is higher than a front surface of the first semiconductor element 404 may be removed, for example, using a grinding process, to expose the front surface of the first semiconductor element 404. The first substrate 402, the first semiconductor element 404 and the mold cap 410 may together form a first semiconductor package 401, which will later be connected with other components.

Next, as shown in FIG. 4D, a back heat sink plate 424 may be mounted on the front surface of the first semiconductor package 401 to at least thermally couple the back heat sink plate 424 with the exposed first semiconductor element 404. In some embodiments, the back heat sink plate 424 may be attached onto the front surface of the first semiconductor element 404 via a thermal interface material layer 414, which can improve heat transfer between the back heat sink plate 424 and the first semiconductor element 404. In the embodiment shown in FIG. 4D, the back heat sink plate 424 may have a heat sink plate connector 428 integrally formed thereon, which is particularly formed as two portions at two opposite edges of the back heat sink 424 in the embodiment. The two portions of the heat sink plate connector 428 may extend upward from the first semiconductor package 401. The back heat sink plate 424 extends along a top surface of the first semiconductor package 401 between the two portions of the heat sink plate connector 428.

Next, as shown in FIG. 4E, an interposer 412 is mounted on the first semiconductor package 401 via the solder bumps (not shown). The interposer 412 may have a first opening 420 and a second opening 422 to allow passage of the respective portions of the heat sink plate connector 428 attached on the back heat sink plate 424. After the interposer 412 is mounted, a top surface or top surfaces of the heat sink plate connector 428 may be flush with or slightly higher than a top surface of the interposer 412. In this way, further components may be easily attached or connected to the heat sink plate connector 428, as will be elaborated below. Furthermore, the interposer 412 may have a set of conductive patterns at its back surface, which can be aligned with and connected with the solder bumps (not shown). In this way, the interposer 412 can be electrically coupled with the first semiconductor package 401. In some embodiments, an additional adhesive material such as a molding material may be filled between the interposer 412 and the first semiconductor package 401 to enhance their connection.

Next, as shown in FIG. 4F, a second semiconductor package 418 is mounted on a front surface of the interposer 412, for example, via solder bumps (not shown). The second semiconductor package 418 may be formed separately. Further, an underfill encapsulant 419 may be formed between the second semiconductor package 418 and the front surface of the interposer 412. The underfill encapsulant 419 may fill in any gaps between the second semiconductor package 418 and the interposer 412. The underfill encapsulant 419 may include a polymer composite material, such as epoxy resin, epoxy acrylate, or polymer with or without a filler. The underfill encapsulant 419 may provide mechanical support to the interconnection between the second semiconductor package 418 and the interposer 412. Next, as shown in FIG. 4G, a front heat sink plate 426 with a central window can be connected to the heat sink plate connector 428 through a thermal interface material layer 430. The central window is generally aligned with and has a bigger size than the second semiconductor package 418. As such, the second semiconductor package 418 can pass through the central window of the front heat sink plate 426 when it is mounted onto the interposer 412, without conflicting with or blocking the second semiconductor package 418.

Next, as shown in FIG. 4H, solder bumps 431 may be mounted on a back surface of the first semiconductor package 401 to function as an interface between the semiconductor package assembly and an external device or system.

After the various steps shown in FIGS. 4A to 4H, the semiconductor package assembly can be obtained.

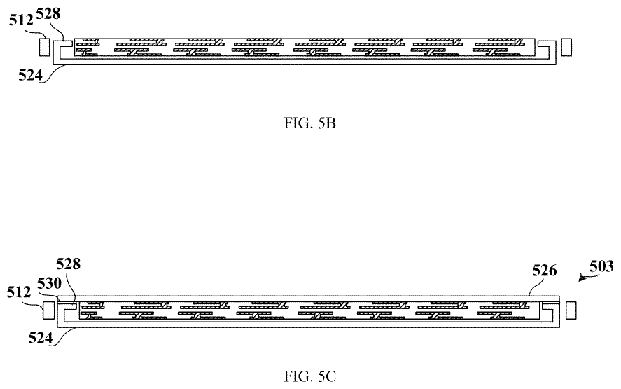

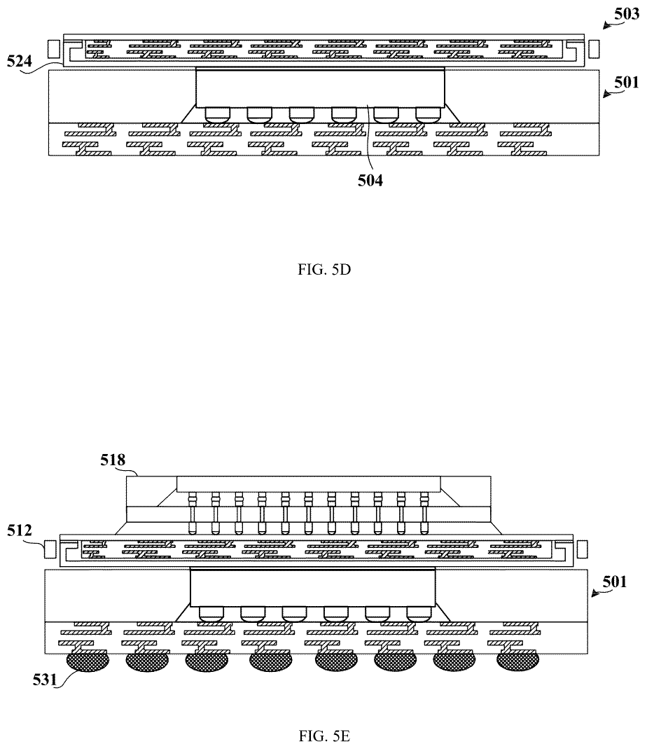

FIGS. 5A to 5E illustrate a method for making a semiconductor package assembly according to an embodiment of the present application. The method may be used to make the semiconductor package assembly 100 shown in FIG. 1A, the semiconductor package assembly 200 shown in FIG. 2, or the semiconductor package assembly 300 shown in FIG. 3 with some modifications.

Different from the embodiment shown in FIGS. 4A to 4H where the front and back heat sink plates and the interposer are separately attached with the first semiconductor package, the method shown in FIGS. 5A to 5E can assemble the heat sink plates and the interposer together prior to attaching them with the first semiconductor package. In particular, FIG. 5A to FIG. 5C illustrate steps for forming an interposer assembly with front and back heat sink plates. As shown in FIG. 5A, an interposer 512 has a set of conductive patterns at its back surface and at least one opening (two openings 520, in the embodiment) passing through the interposer 512. As shown in FIGS. 5B and 5C, a back heat sink plate 524 and a front heat sink plate 526 are attached on back and front surfaces of the interposer 512, respectively. Furthermore, the back heat sink plate 524 and the front heat sink plate 526 are thermally connected with each other by a heat sink plate connector 528 that passes through the at least one opening, which can be either integrally formed with one of the front and back heat sink plates 526 and 524, or be formed separately from the plates.

As shown in FIG. 5D, the interposer assembly 503 is mounted on a front surface of the first semiconductor package 501 to at least thermally couple the back heat sink plate 524 with the exposed first semiconductor element 504, which can improve the heat transfer between the back heat sink plate 524 and the first semiconductor element 504.

Next, as shown in FIG. 5E, a second semiconductor package 518 is mounted on a front surface of the interposer 512, for example, via solder bumps. The second semiconductor package 518 may be formed separately. Solder bumps 531 may be mounted on a back surface of the first semiconductor package 501 to function as an interface between the semiconductor package assembly and an external device or system.

After the various steps shown in FIGS. 5A to 5E, the semiconductor package assembly can be obtained. The package assembly has two layers of semiconductor packages with an embedded heat sink that facilitates heat dissipation from the interior to the exterior of the package assembly, and improves mechanical strength of the package assembly.

The discussion herein includes numerous illustrative figures that show various portions of a semiconductor package assembly with dual heat sink plates and a method for making such semiconductor package assembly. For illustrative clarity, such figures do not show all aspects of each example semiconductor package. Any of the example packages provided herein may share any or all characteristics with any or all other packages provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package assembly, comprising:
a first semiconductor package comprising a first semiconductor element and a first set of conductive patterns both exposed from a front surface of the first semiconductor package;
an interposer mounted on the front surface of the first semiconductor package via a set of interconnect structures, wherein the interposer comprises at its back surface a second set of conductive patterns which are aligned with the first set of conductive patterns such that the first and second sets of conductive patterns are electrically connected with each other through the set of interconnect structures; and wherein the interposer further comprises at least one opening extending through the interposer;
a second semiconductor package mounted on a front surface of the interposer; and
a heat sink; wherein the heat sink comprises:
a back heat sink plate mounted between the first semiconductor package and the interposer, and thermally coupled with the first semiconductor element;
a front heat sink plate mounted between the interposer and the second semiconductor package, and being in contact with the front surface of the interposer; and
a heat sink plate connector extending through the at least one opening and connecting the back heat sink plate and the front heat sink plate to allow heat to be transferred from the back heat sink plate to the front heat sink plate.

2. The semiconductor package assembly of claim 1, wherein the at least one opening further comprises a first opening and a second opening formed on two opposite sides of the interposer relative to the second semiconductor package; and the heat sink plate connector comprises respective portions extending through the first opening and the second opening.

3. The semiconductor package assembly of claim 1, wherein the back heat sink plate is integrally formed with the heat sink plate connector, and the front heat sink plate is connected to the heat sink plate connector through a thermal interface material layer.

4. The semiconductor package assembly of claim 3, wherein the heat sink plate connector extends from the back heat sink plate to the front heat sink plate, and has an increased contact surface at a position where it is connected to the front heat sink plate to allow for connection with the front heat sink plate through the thermal interface material layer.

5. The semiconductor package assembly of claim 1, wherein the front heat sink plate is shaped as a frame, and has a central window for passing the second semiconductor package.

6. The semiconductor package assembly of claim 1, wherein the first semiconductor package further comprises:
a first substrate where the first semiconductor element is mounted;
a set of conductive structures mounted on the first substrate;
a mold cap encapsulating the first semiconductor element and the set of conductive structures, wherein the mold cap forms the front surface of the first semiconductor package and exposes a front surface of the first semiconductor element and front surfaces of the set of conductive structures as the first set of conductive patterns.

7. The semiconductor package assembly of claim 1, wherein the semiconductor package assembly further comprises:
an additional heat sink attached to the front heat sink plate of the heat sink and thermally connected to the front heat sink plate.

8. The semiconductor package assembly of claim 7, wherein the additional heat sink is shaped as a cover, and defines a cavity for accommodating the second semiconductor package, wherein the second semiconductor package is thermally connected to the additional heat sink through a thermal interface material layer to allow heat to be transferred from the second semiconductor package to the additional heat sink.

9. A method for making a semiconductor package assembly, the method comprising:
providing a first semiconductor package, wherein the first semiconductor package comprises a first semiconductor element and a first set of conductive patterns exposed from a front surface of the first semiconductor package;
attaching a set of interconnect structures on the front surface of the first semiconductor package and electrically connecting the set of interconnect structures with the first set of conductive patterns;
mounting a back heat sink plate on the front surface of the first semiconductor package to at least thermally couple the back heat sink plate with the exposed first semiconductor element, wherein a heat sink plate connector extends away from the back heat sink plate;
mounting an interposer on the front surface of the back heat sink plate, wherein the interposer comprises at its back surface a second set of conductive patterns which are aligned with the first set of conductive patterns such that the first and second sets of conductive patterns are electrically connected with each other through the set of interconnect structures, and wherein the interposer comprises at least one opening extending through the interposer to allow the heat sink plate connector to pass through the at least one opening;
mounting a second semiconductor package on a front surface of the interposer; and
mounting a front heat sink plate on the front surface of the interposer to connect the front heat sink plate with the back heat sink plate through the heat sink plate connector.

10. The method of claim 9, wherein the step of mounting the second semiconductor package on the front surface of the interposer is prior to the step of mounting the front heat sink plate on the front surface of the interposer, and the front heat sink plate is shaped as a frame with a central window; and mounting the front heat sink plate on the front surface of the interposer further comprises:
passing the second semiconductor package through the central window of the front heat sink plate, and connecting the front heat sink plate with the heat sink plate connector.

11. The method of claim 10, wherein before the step of mounting the back heat sink plate on the front surface of the first semiconductor package, the method further comprises:
forming a thermal interface material layer on the exposed first semiconductor element.

12. The method of claim 9, wherein before the step of mounting the front heat sink plate on the front surface of the interposer, the method further comprises:
forming a thermal interface material layer on a surface of the heat sink plate connector.

13. The method of claim 9, wherein the at least one opening further comprises a first opening and a second opening on two opposite sides of the interposer relative to the second semiconductor package; and the heat sink plate connector comprises respective portions extending through the first opening and the second opening.

14. The method of claim 9, wherein after the step of mounting the second semiconductor package on the front surface of the interposer and the step of mounting the front heat sink plate on the front surface of the interposer, the method further comprises:
attaching an additional heat sink on the front heat sink plate.

15. The method of claim 14, wherein the additional heat sink is shaped as a cover, and defines a cavity for accommodating the second semiconductor package, wherein the second semiconductor package is thermally connected to the additional heat sink through a thermal interface material layer to allow heat to be transferred from the second semiconductor package to the additional heat sink.

16. A method for making a semiconductor package assembly, the method comprising:
providing a first semiconductor package, wherein the first semiconductor package comprises a first semiconductor element and a first set of conductive patterns exposed from a front surface of the first semiconductor package;
attaching a set of interconnect structures on the front surface of the first semiconductor package and electrically connecting the set of interconnect structures with the first set of conductive patterns;
providing an interposer assembly; wherein the interposer assembly comprises an interposer with a second set of conductive patterns at a back surface of the interposer, and at least one opening passing through the interposer; the interposer assembly further comprises a back heat sink plate attached on the back surface of the interposer and a front heat sink plate attached on the front surface of the interposer; and wherein the back heat sink plate and the front heat sink plate are thermally connected with each other through a heat sink plate connector that passes through the at least one opening;
mounting the interposer assembly on the front surface of the first semiconductor package via the set of interconnect structures, wherein the second set of conductive patterns are aligned with the first set of conductive patterns such that the first and second sets of conductive patterns are electrically connected with each other through the set of interconnect structures; and
mounting the second semiconductor package on the front surface of the interposer.

17. The method of claim 16, wherein before the step of mounting the interposer assembly on the front surface of the first semiconductor package, the method further comprises:
forming a thermal interface material layer on the exposed first semiconductor element.

18. The method of claim 16, wherein before the step of mounting the front heat sink plate on the front surface of the interposer, the method further comprises:
forming a thermal interface material layer on a surface of the heat sink plate connector.
